(19) United States
(12) Patent Application Publication
(10) Pub. No.: US 2026/0063665 A1
(43) Pub. Date: Mar. 5, 2026

(54) ELECTRICAL CONTACTOR AND ELECTRICAL CONNECTING APPARATUS

(71) Applicant: KABUSHIKI KAISHA NIHON MICRONICS, TOKYO (JP)

(72) Inventor: TOMOAKI KUGA, TOKYO (JP)

(21) Appl. No.: 19/285,550

(22) Filed: Jul. 30, 2025

(30) Foreign Application Priority Data
Aug. 6, 2024 (JP) 2024-129872

(51) Int. Cl. G01R 1/04; G01R 1/067; G01R 1/073

(52) U.S. Cl. CPC G01R 1/0441; G01R 1/06755; G01R 1/07342

(57) ABSTRACT

An electrical contactor includes a main body unit; a first contact portion which is one tip portion of the main body unit and is in contact with a first contact object; and a second contact portion which is the other tip portion of the main body unit and is in contact with a second contact object, wherein the electrical contactor is made of a conductive ceramic material containing titanium. The electrical contactor may be included in an electrical connecting apparatus having a plurality of electrical contactors, wherein the first contact portion is in contact with an electrode portion of a device under test housed in the housing and the second contact portion is in contact with wiring formed on the substrate.

### CROSS-REFERENCE TO RELATED APPLICATIONS

The present application claims priority under 35 U.S.C. § 119 to Japanese Patent Application No. 2024-129872 filed on Aug. 6, 2024. The contents of this application are incorporated herein by reference in their entirety.

### TECHNICAL FIELD

The present disclosure relates to an electrical contactor and can be applied to, for example, an electrical contactor and an electrical connecting apparatus in electrical contact with an electrode terminal of a semiconductor apparatus (also called a “semiconductor device” or “semiconductor integrated circuit”).

### BACKGROUND ART

When testing electrical characteristics of a device in which a semiconductor integrated circuit or the like is mounted in a package, a probe device has been used to establish an electrical connection between the device and a test apparatus. The probe device electrically connects the electrode terminal of the device to an electrode pad disposed on a substrate, such as a printed circuit board (PCB). The electrode pad is electrically connected to the test apparatus through a wiring pattern or the like formed on the substrate.

Conventionally, electrical contactors such as probes and pogo pins require high hardness to be processable in ways such as wire drawing, bending, and cutting of metallic materials, and withstand repeated contact with contact objects such as electrode terminals. For this reason, the electrical contactors are made of a metallic material, such as a palladium alloy (refer to Patent Literature 1).

### CITATION LIST

### Patent Literature

Patent Literature 1: Japanese Patent Application Laid-Open Publication No. 2020-035866

### SUMMARY OF INVENTION

### Technical Problem

However, repeated contact between the electrode terminals of the semiconductor device and the electrical contactors causes the electrical contactors to wear out, and metals, such as tin and palladium alloy, then adhere to the electrode terminals, resulting in a problem of poor contactability.

Moreover, in order to improve the contactability, such metals are mechanically removed, for example with a brush or cleaning sheet, but this cleaning may cause the electrical contactors to wear and deform, resulting in a problem of poor contactability. Moreover, there is also a problem that a service life of the electrical contactors is shortened.

Accordingly, in view of the above-described problems, the present disclosure aims to provide an electrical contactor and an electrical connecting apparatus having high hardness, high wear resistance, and excellent electrical conductivity.

### Solution to Problem

In order to solve such problems, an electrical contactor according to a first aspect of the present disclosure comprises: a main body unit; a first contact portion which is one tip portion of the main body unit and is in contact with a first contact object; and a second contact portion which is the other tip portion of the main body unit and is in contact with a second contact object, wherein the electrical contactor is made of a conductive ceramic material containing titanium.

An electrical connecting apparatus according to a second aspect of the present disclosure comprising a housing provided on a substrate on which wiring is formed, the electrical connecting apparatus configured to connect between an electrode portion of a device under test housed in the housing and the wiring, the electrical connecting apparatus comprises a plurality of contactors including a first contact portion in contact with the electrode portion of the device under test housed in the housing and a second contact portion in contact with the wiring formed on the substrate, wherein each contactor is the electrical contactor according to the first aspect of the present disclosure.

### Advantageous Effects of Invention

According to the present disclosure, it is possible to provide the electrical contactor having high hardness, high wear resistance, and excellent electrical conductivity, and is possible to provide the electrical connecting apparatus having high contactability by using the electrical contactor.

### BRIEF DESCRIPTION OF DRAWINGS

FIG. 1 is a configuration diagram illustrating a configuration of an electrical connecting apparatus according to an embodiment.

FIG. 2 is a configuration diagram illustrating a state of a probe at the time of contact, in the electrical connecting apparatus according to the embodiment.

FIG. 3 is a diagram illustrating characteristics of conductive ceramic according to the embodiment.

FIG. 4 is a configuration diagram illustrating a configuration of a probe according to a modified embodiment.

FIG. 5 is a configuration diagram illustrating a configuration of a connector according to the modified embodiment.

### DESCRIPTION OF EMBODIMENTS

### (A) Principal Embodiment

Hereinafter, an embodiment of an electrical contactor and an electrical connecting apparatus according to the present disclosure will be described in detail with reference to the drawings.

The “electrical contactor” disclosed herein is a conductive contactor capable of coming into contact with first and second contact objects. For example, connectors can be applied as the “electrical contactor”, including probes (including vertical type probes and cantilever type probes) that are in contact with electrode terminals of a device under test, and pogo pins that connect between respective wiring terminals of two substrates. The present embodiment exemplifies a case of a probe used for a test socket as an example of the electrical contactor according to the present disclosure.

The “first contact object” is an object with which one end portion of the electrical contactor comes into contact, and the “second contact object” is an object with which the other end portion of the electrical contactor comes into contact. Therefore, it is only necessary that the objects with which the electrical contactor comes into contact are different from each other. For example, in a case of a probe, the first contact object may be a wiring pattern (connection terminal) on a substrate, and the second contact object may be an electrode terminal of a device under test. Alternatively, for example, in a case of a pogo pin, the first contact object may be a connection terminal (first connection terminal) on a first substrate, and the second contact object may be a connection terminal (second connection terminal) on a second surface (e.g., lower surface) of a second substrate.

The “electrical connecting apparatus” is an electrical connecting apparatus that is interposed between a semiconductor test apparatus and a device under test to establish an electrical connection therebetween; and testing jigs, such as a probe card and a socket, can be applied. The present embodiment exemplifies a case of a test socket being used as the electrical connecting apparatus.

### (A-1) Configuration of Electrical Connecting Apparatus

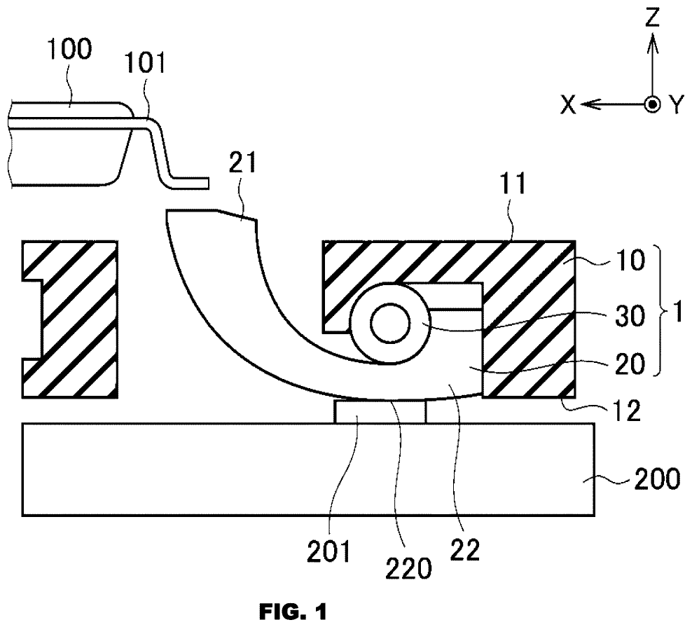

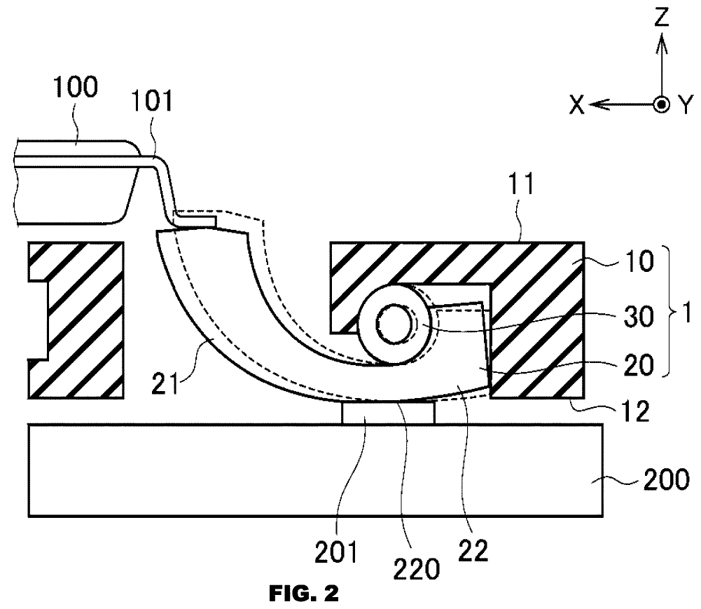

FIG. 1 is a configuration diagram illustrating a configuration of an electrical connecting apparatus according to an embodiment. FIG. 2 is a configuration diagram illustrating a state of a probe at the time of contact, in the electrical connecting apparatus according to the embodiment.

It is to be noted that each drawing illustrates the main components, but the present disclosure is not limited to the illustrated components and may also include components that are not actually illustrated. In the description of each drawing, the identical or similar reference sign is attached to the identical or similar part. However, it should be noted that the drawings are schematic and the thickness and the size of each component part differs from the actual thing. Moreover, the size and the ratio of corresponding component parts differ among drawings. The embodiments described hereinafter merely exemplify the device and method for materializing the technical idea of the disclosure, and the embodiments do not limit the material, shape, structure, arrangement, etc. of each component part disclosed herein.

In FIG. 1, a probe device 1 according to the embodiment is a test socket used for testing electrical characteristics of a device under test 100 as a test object.

The device under test 100 may be a semiconductor apparatus (semiconductor device) mounted in a package, such as a semiconductor integrated circuit. The probe device 1 establishes an electrical connection between an electrode terminal 101 of the device under test 100 and an electrode pad 201 on a substrate 200. FIG. 1 illustrates an example of a case where the electrode terminal 101 is a lead electrode of the package. The electrode pad 201 is electrically connected to the test apparatus through a wiring pattern (not illustrated) or the like formed on the substrate 200.

A probe device 1 includes a housing 10 including a first surface 11 and a second surface 12 opposite to the first surface 11, a probe 20 including a first contact portion 21 and a second contact portion 22 and supported by the housing 10, and an elastic portion 30 disposed inside the housing 10.

The probe 20 functions as a contactor that electrically connects between the electrode terminal 101 and the electrode pad 201. Hereinafter, the first and second contact portions 21 and 22 will also be referred to as “contact portions” when they are not limited.

In the probe 20, at least the first contact portion 21 in contact with the electrode terminal 101 and the second contact portion 22 in contact with the electrode pad 201 are made of a conductive ceramic material having high hardness. The portions of the probe 20 that are not made of conductive ceramic material are made of a conductive material such as a metal material.

For example, the probe 20 may have a structure in which a metallic material, such as a beryllium copper (Be—Cu) material or a palladium (Pd) alloy material, is used for a material of a portion between the first contact portion 21 and the second contact portion 22 of the conductive ceramic material. Alternatively, the entire probe 20 including the contact portion may be made of a conductive ceramic material having high hardness. The present embodiment describes an example of a case where the entire probe 20 is made of a conductive ceramic material having high hardness.

The elastic portion 30 is disposed inside the housing 10 so as to be in contact with the housing 10 and the probe 20.

In order to give an easy-to-understand description of an operation of a probe device 1, the X, Y, and Z directions are defined, as illustrated in FIG. 1. In FIG. 1, the X direction is the left-right direction on the drawing sheet, the Y direction is the depth direction on the drawing sheet, and the Z direction is the up-down direction on the drawing sheet. Moreover, in the Z direction, the direction where the device under test 100 is located as viewed from the probe device 1 is defined as the upward direction, and the direction where the probe device 1 is located as viewed from the device under test 100 is defined as the downward direction.

Although FIG. 1 illustrates only one probe 20 in the probe device 1, the probe device 1 may have a plurality of probes 20. For example, the probe device (electrical connecting apparatus) 1 may be configured to have a plurality of probes 20 arranged along the Y direction.

A thickness of the probe 20 in the Y direction (hereinafter also simply referred to as “thickness”) is, for example, approximately 0.1 to 0.2 mm. The thickness of the probe is not limited to 0.1 to 0.2 mm and can be freely set according to a size and spacing of the electrode terminal 101, magnitude of a current flowing through the probe 20, or the like when testing the device under test 100.

The probe 20 may be formed, for example, by cutting a plate of a conductive ceramic material into a predetermined shape by using wire electric discharge machining or laser processing. Therefore, processing accuracy of the thickness of the probe 20 can be more improved than when forming the probe 20 by processing a metal material. That is, processing variations in the thickness of the probe 20 are less likely to occur when the probe 20 is made of the conductive ceramic material. In contrast, metallic materials are softer than conductive ceramic materials, therefore, processing variations in the thickness of the probe 20 made of metallic materials occur easily.

In FIG. 1, the probe device 1 is disposed below the device under test 100 when viewed from the Z direction.

The first contact portion 21 of the probe 20 is exposed from the first surface 11 of the housing 10, and the second contact portion 22 of the probe 20 is exposed from the second surface 12 of the housing 10. The probe 20 is disposed in the housing 10 so that the electrode terminal 101 of the device under test 100 comes into contact with the first contact portion 21 when the spacing between the probe device 1 and the device under test 100 narrows along the Z direction. Furthermore, the probe 20 is disposed in the housing 10 so that a contact region 220 of the second contact portion 22 comes into contact with the electrode pad 201 on the substrate 200.

During testing of the device under test 100, a position of the contact region 220 of the second contact portion 22 in contact with the electrode pad 201 changes due to a change in a position of first contact portion 21 in the Z direction. The change in the state of the probe 20 during testing will be described in detail later, with reference to FIG. 2.

When viewed in the Y direction, the probe 20 has a curved shape in which a recessed portion is formed face-up. One end portion of the probe 20 located away from an outer portion of the probe 20 opposite to the recessed portion (hereafter referred to as the “curved portion”) is the first contact portion 21. The other end portion of the probe 20 close to the recessed portion is the second contact portion 22. A portion of an arc-shaped region of an outer edge of the curved portion is the contact region 220. When an X-Y plane defined by the X direction and the Y direction is used as a projection plane, a projection line in a direction connecting between the first contact portion 21 and the second contact portion 22 (hereinafter referred to as the “extending direction” of the probe 20) extends in the X direction. In other words, when viewed from the Z direction, the probe 20 extends in the X direction.

The elastic portion 30 has a cylindrical shape, and an axial direction thereof extends in the Y direction. That is, the axial direction of the elastic portion 30 is a direction perpendicular to a direction where the first contact portion 21 of the probe 20 is displaced and perpendicular to a direction where the probe 20 extends. The elastic portion 30 is in contact with the inside of the recessed portion of the probe 20. In other words, the elastic portion 30 is disposed to be sandwiched between a surface of the recessed portion of the probe 20 and an inner wall of the housing 10.

During testing of the device under test 100, as illustrated in FIG. 2, the electrode terminal 101 of the device under test 100 and the electrode pad 201 on the substrate 200 are electrically connected to each other through the conductive probe 20.

In other words, during testing of the device under test 100, the device under test 100 is relatively moved to the probe device 1 along the Z direction, and the first contact portion 21 of the probe 20 is pressed against the electrode terminal 101 of the device under test 100. At this time, due to the pressing force applied to the first contact portion 21 between the first contact portion 21 and the electrode terminal 101, the posture of the probe 20 changes inside the housing 10 in a state where the second contact portion 22 is in contact with the surface of the electrode pad 201.

Specifically, the posture of the probe 20 changes inside the housing 10 while the second contact portion 22 remains in contact with the electrode pad 201, in response to the displacement of the first contact portion 21 in the Z direction caused by the pressing force applied to the first contact portion 21. As the posture of the probe 20 changes, the position of the contact region 220 of the second contact portion 22 in contact with the electrode pad 201 changes.

In FIG. 2, the solid line illustrates the posture of the probe 20 and the shape of the elastic portion 30 in the state where the first contact portion 21 is in contact with the electrode terminal 101 (hereinafter also referred to as the “contact state”). In contrast, the dashed line illustrates the posture of the probe 20 and the shape of the elastic portion 30 in a state where the electrode terminal 101 is not in contact with the first contact portion 21 (hereinafter also referred to as the “non-contact state”).

In the case of the contact state during testing of the device under test 100, the posture of the probe 20 changes so that the position of the contact region 220 is closer to the first contact portion 21 than in a non-contact state.

It is required that the probe 20 has electrical conductivity for electrically connecting the electrode terminal 101 and the electrode pad 201, and mechanical strength so that the shape does not change between the contact state and the non-contact state. The probe 20, which is made of the conductive ceramic material, has both electrical conductivity and mechanical strength.

In the contact state, the elastic portion 30 is sandwiched between the probe 20 and the housing 10 to be compressed in response to the change in the posture the probe 20 inside the housing 10. That is, in the contact state, the elastic portion 30 is elastically deformed. The elastically deformed elastic portion 30 biases the probe 20 in a direction to return the posture of the probe 20 to its posture in the non-contact state. In other words, the elastic portion 30 biases the probe 20 so as to press the first contact portion 21 against the electrode terminal 101.

During testing of the device under test 100, the first contact portion 21 remains in contact with the electrode terminal 101 and the second contact portion 22 remains in contact with the electrode pad 201, due to the elastic force of the elastic portion 30. Consequently, during testing of the device under test 100, the electrical connection between the electrode terminal 101 of the device under test 100 and the electrode pad 201 on the substrate 200 is ensured through the probe 20.

In the probe device 1, the contact region 220, which is a portion of the arc-shaped region on the outer edge of the curved portion of the probe 20, is in contact with the electrode pad 201 along a line extending in the Y direction. Moreover, as illustrated in FIG. 2, the position of the contact region 220 in the contact state is closer to the first contact portion 21 than the position of the contact region 220 in the non-contact state. The position of the contact region 220 changes between the contact state and the non-contact state because the position of the contact region 220 changes along the outer edge of the curved portion in response to the change in the posture of the probe 20. Since the arc-shaped region of the curved portion includes the contact region 220, the position of the contact region 220 in contact with the electrode pad 201 smoothly changes in response to the change in the posture of the probe 20. Therefore, it is possible to suppress damage to the second contact portion 22 and the electrode pad 201 even when the posture of the probe 20 changes.

As described above, during testing of the device under test 100, the posture of the probe 20 changes, causing the elastic portion 30 sandwiched between the probe 20 and the housing 10 to elastically deform. Then, the elastic portion 30 biases the probe 20 so that the first contact portion 21 comes into contact with the electrode terminal 101 of the device under test 100 with a predetermined pressure.

That is, the elastic portion 30 biases the probe 20 in a direction that cancels the displacement of the first contact portion 21 caused by the pressing force applied to the first contact portion 21 when the first contact portion 21 is pressed against the electrode terminal 101. During testing of the device under test 100, i.e., while the first contact portion 21 is in contact with the electrode terminal 101, the elastic portion 30 is in a compressively deformed state.

After the test of the device under test 100 is completed, the position of the device under test 100 in the Z direction relative to the probe device 1 is changed so as to extend the spacing between the device under test 100 and the probe device 1. By separating the electrode terminal 101 of the device under test 100 from the first contact portion 21 of the probe 20, the pressing force applied to the first contact portion 21 is eliminated. As a result, the shape of the elastic portion 30 is restored to the shape in the non-contact state, and the posture of the probe 20 is also restored to the posture in the non-contact state due to the elastic force of the elastic portion 30.

The probe 20 is supported by the housing 10 so that the posture of the probe 20 can change in response to the displacement of the position of the first contact portion 21 in the Z direction. The posture of the probe 20 changes inside the housing 10 so that the position of the contact region 220 of the second contact portion 22 in contact with the electrode pad 201 changes in response to the displacement of first contact portion 21 in the Z direction. For example, although not illustrated, a portion of the probe 20 may be protruded, and the protrusion portion of the probe 20 may be inserted into a support hole formed in the housing 10. Alternatively, a portion of the probes 20 may be placed on a support unit of the housing 10 provided below the probe 20.

As described above, the probe device 1 includes the probe 20 made of the conductive ceramic material simultaneously in contact with the electrode terminal 101 and the electrode pad 201, and the elastic portion 30 that biases the probe 20 by the elastic force when the probe 20 is in contact with the electrode terminal 101.

A contact load applied to the probe 20 when the probe 20 and the electrode terminal 101 come into contact with each other is controlled by the elastic force of the elastic portion 30. By increasing the elastic force of the elastic portion 30, the contact load increases, and by decreasing the elastic force of the elastic portion 30, the contact load decreases.

Moreover, in the probe device 1, an amount of displacement (hereinafter also referred to as “stroke”) of the first contact portion 21 due to contact with the electrode terminal 101 is controlled by the elastic force of the elastic portion 30. That is, by increasing the elastic force of the elastic portion 30, the stroke decreases, and by decreasing the elastic force of the elastic portion 30, the stroke increases.

The elastic portion 30 is made of a material such as an elastomer. The elastic portion 30 may also be formed in a cylindrical shape having a hollow structure. By forming the elastic portion 30 in the cylindrical shape, it is easy to control the contact load and the magnitude of the stroke. That is, by increasing the thickness of the cylindrical elastic portion 30, the contact load can be increased and the stroke can be decreased. In contrast, by decreasing the thickness of the cylindrical elastic portion 30, the contact load can be decreased and the stroke can be increased.

The elastic portion 30 may be made of a conductive material or an insulating material. However, the materials of the housing 10 and the elastic portion 30 and the arrangement of the elastic portion 30 inside the housing 10 are set so that the probes 20 are electrically insulated from each other.

### (A-2) Detailed Description of Probe 20

Conventionally, metallic materials have been used for a contactor that electrically connects between the electrode terminal 101 and the electrode pad 201. The contactor corresponds to the probe 20 in the probe device 1. By repeating testing of the device under test 100, the metallic material (such as tin or nickel palladium (Ni—Pd)) of the electrode terminal 101 and the electrode pad 201 adheres to the surface of the contactor. In order to prevent the contactor between the electrode terminal 101 and the electrode pad 201 from deteriorating the contactability, it is necessary to remove the metal adhering to the surface of the contactor by a cleaning operation.

However, due to the physical cleaning operation, the surface of the contactor may be worn or damaged, and the probe may be deformed, reducing the contactability of the contactor. As a result, the accuracy of the test may be affected.

Therefore, in the probe device 1, the probe 20 is made of a conductive ceramic material, which is harder and more wear-resistant than metallic materials, thereby suppressing the deterioration of the contactability of the probe 20.

For example, according to the probe device 1, it is possible to suppress wear of the probe 20 due to a cleaning operation for removing metal adhering to the surface of the probe 20. Moreover, according to the probe device 1, it is possible to establish stable contact between the probe 20 and the electrode terminal 101 and the electrode pad 201.

### (A-3) Detailed Description of Conduction Ceramic

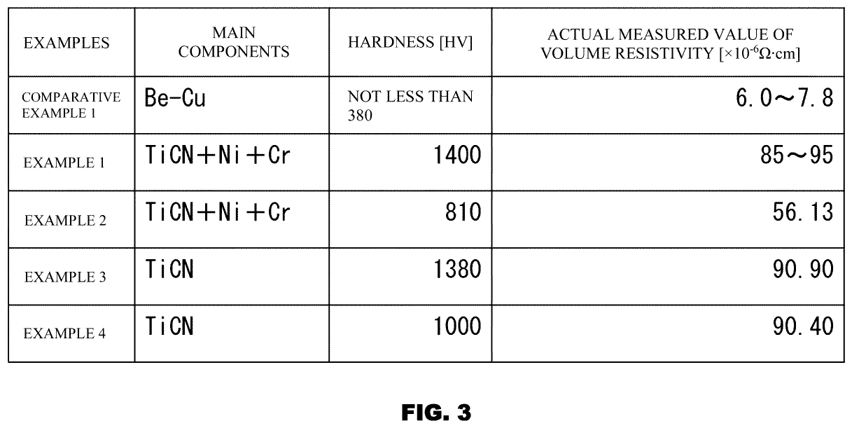

FIG. 3 is a diagram illustrating characteristics of conductive ceramic according to the embodiment.

FIG. 3 illustrates the characteristics of beryllium copper (Be—Cu) as typical metallic materials of conventional probes (labeled “Comparative Example 1”), and the characteristics (labeled “Examples 1 to 4”) of titanium carbonitride or materials containing titanium carbonitride exemplified in the present embodiment, showing, for example, hardness (Vickers hardness) and a volume resistivity for each example.

As examples of conductive ceramic having high hardness, conductive ceramic containing titanium carbonitride as a main component, as in Examples 1 to 4, are listed.

Examples 1 and 2 use conductive ceramic containing titanium carbonitride, nickel, and chromium as the main components, and Examples 3 and 4 use conductive ceramic containing titanium carbonitride as the main component.

From the viewpoint of favorable electrical conductivity, the volume resistivity of the probe 20 is preferably not more than approximately 100 [×10⁻⁶ Ω·cm], and more preferably not more than 60 [×10⁻⁶ Ω·cm], for example. Thus, favorable electrical conductivity can be ensured by setting the volume resistivity of the probe 20 to not more than approximately 100 [×10⁻⁶ Ω·cm].

From the viewpoint of wear resistance, the hardness of the probe 20 is preferably, for example, not less than 800 HV, more preferably not less than 1000 HV, and still more preferably not less than 1380 HV. Thus, by setting the hardness of the probe 20 and the like to not less than 800 HV, i.e., to be higher than the hardness of metallic materials, metal debris is less likely to be generated during contact and the probe is less likely to be scraped off during cleaning, thereby suppressing deformation and improving contactability.

As described above, titanium-based ceramic is suitable as conductive ceramic having high hardness and favorable electrical conductivity, and ceramic containing titanium carbonitride as the main component and composite ceramic containing titanium carbonitride (hereinafter referred to as “titanium carbonitride-based ceramic”) are more preferable.

Moreover, by using the titanium carbonitride-based ceramic as the material for the probe 20, tip processing (e.g., peaked tip processing) of the probe 20 is facilitated. For example, by peaked tip processing, the contact surface of the probe 20 with respect to the metal terminals such as electrode terminals of the device under test can be easily processed, thereby improving contactability.

Furthermore, by using conductive ceramic for the probe 20, the maximum operating temperature becomes higher. It is also possible to suppress deformation of the probe 20 and it is also possible to extend the service life of the probe 20.

### (A-4) Advantageous Effects of Embodiment

As described above, according to the present embodiment, since the electrical contactor is made of the titanium carbonitride-based ceramic, it is possible to increase the hardness, thereby suppressing wear during cleaning and improving contactability. It is also possible to extend the service life. Moreover, since the volume resistivity is low, it is possible to maintain the electrical conductivity.

Moreover, by using the electrical contactor made of the titanium carbonitride-based ceramic to perform electrical testing of the device under test, the contactability of the probes and the like is improved, enabling highly accurate testing.

### (B) Other Embodiments

Although in the above-described embodiment, the electrical contactor and the electrical connecting apparatus according to the present disclosure have been described, the present disclosure can also be applied to the following modified embodiments.

(B-1) In the above-described embodiment, the electrical contactor made of the titanium carbonitride-based ceramic as the high-hardness conductive ceramic has been exemplified, but the electrical contactor may be partially plated with metal plating or the like.

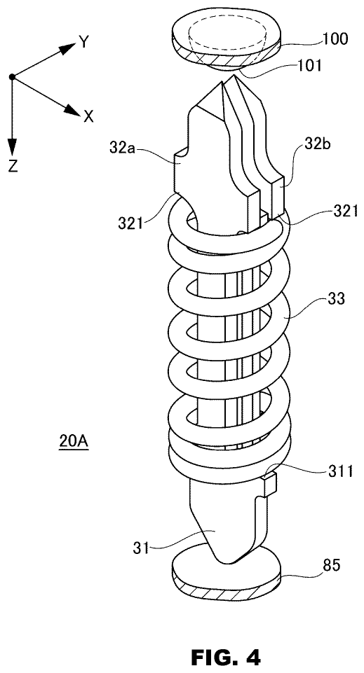

(B-2) A modified example of the probe is illustrated using FIG. 4. In this modified embodiment, a vertical type probe is illustrated, but the structure of the vertical type probe is not limited to that illustrated in FIG. 4.

As illustrated in FIG. 4, a probe 20A includes one first plunger 31, two second plungers 32 (32a, 32b), and one coil spring 33.

Each of the first plunger 31 and the second plungers 32 (32a, 32b) is a plate-shaped member, and the two second plungers 32 (32a, 32b) are provided so as to sandwich both surfaces of the first plunger 31. The coil spring 33 is provided so as to cover an outer periphery of a portion where the second plungers 32 (32a and 32b) and the first plunger 31 overlap.

The first plunger 31 includes a coil receiving portion 311 that is wider than an end portion to be inserted into the coil spring 33. Similarly, the second plunger 32 (32a, 32b) also includes a coil receiving portion 321 wider than an end portion to be inserted into the coil spring 33. Both of end portions of the coil spring 33 are respectively supported by the coil receiving portion 311 and the coil receiving portion 321. Therefore, when a contact load is applied to the first plunger 31 and the second plunger 32 (32a, 32b) during testing, the coil spring 33 has elasticity in the Z-axis direction, allowing the probe 20A to move up and down (in the Z-axis direction).

In a method of assembling the probe 20A using the first plunger 31, the second plungers 32 (32a, 32b), and the coil spring 33, for example, the two second plungers 32 (32a, 32b) are inserted from one end portion of the coil spring 33. Next, the first plunger 31 is inserted from the other end portion of the coil spring 33 so that the first plunger 31 is fitted between the two second plungers 32. It is to be noted that the method of assembling the probe 20A is not limited to the above-described method.

The probe 20A illustrated in FIG. 4 is also made of a conductive ceramic material having high hardness, in particular, is made of a conductive ceramic material containing titanium carbonitride as a main component.

For example, all of the components (members) of the first plunger 31, the second plungers 32 (32a, 32b), and the coil spring 33 are made of conductive ceramic. Alternatively, for example, some of the members of the first plunger 31, the second plungers 32 (32a, 32b), and the coil spring 33 may be made of conductive ceramic. For example, the first plunger 31 and the second plunger 32 may be made of conductive ceramic, and the coil spring 33 may be made of metal.

Alternatively, the first plunger 31, the second plungers 32 (32a, 32b), and the coil spring 33 may each be made of conductive ceramic, or only a portion of each member may be made of conductive ceramic.

When the probe 20A is processed using conductive ceramic, a method can be used in which a plate material made of the conductive ceramic is cut by wire electric discharge machining or laser processing to process the outer shape thereof. This makes it possible to reduce the number of processes, such as wire drawing and bending of metal materials, that are required in the conventional art. When cutting out the metal plate material using wire electric discharge machining or the like, burrs are generated on the cut surface. However, when cutting out conductive ceramic plate material, burrs are less likely to be generated on the cut surface, improving processing accuracy.

The probe 20A comes into contact with the electrode terminal 101 of the device under test 100 and the connection terminal 85 on the substrate, and sufficient mechanical strength is required because of the high contact frequency. In other words, the conductive ceramic material is required to have high hardness. Furthermore, the conductive ceramic material is required to have electrical conductivity.

(B-3) Next, an example will be given in which connectors such as pogo pins are also made of conductive ceramic having high hardness containing titanium carbonitride as a main component.

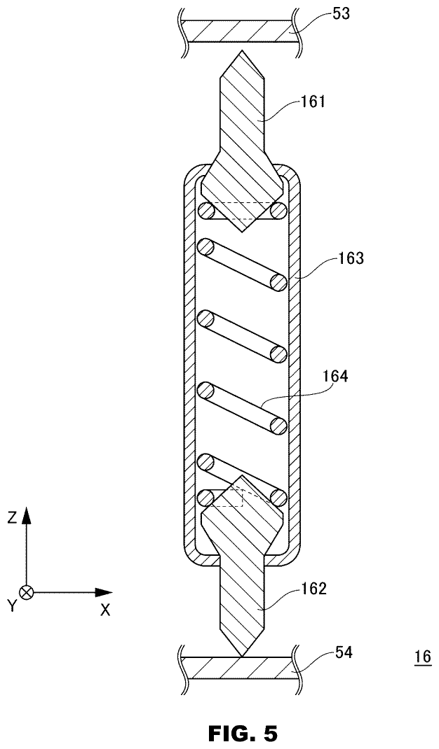

In FIG. 5, a connector 16 can use an existing pogo pin, for example, including a third plunger 161, a fourth plunger 162, a barrel 163, and a coil spring 164.

Although the connector 16 is illustrated as the pogo pin in FIG. 5 in this modified example, the structure of the connector 16 is not limited to that illustrated in FIG. 5, and the connector 16 may be not only a pogo pin but also a rod or the like.

The third plunger 161 and the fourth plunger 162 are each a generally cylindrical or circular columnar member having a peaked tip, protruded from the end portion of the cylindrical barrel 163. The coil spring 164 is provided inside the barrel 163 so as to be fixed to an end portion of the third plunger 161 and an end portion of the fourth plunger 162. This gives connector 16 elasticity in the Z-axis direction.

Here, the connectors 16 are connected to a terminal 53 of a wiring substrate (first substrate) and to a connection terminal 54 of the connection wiring substrate (second substrate) and are required to have sufficient mechanical strength. Of course, electrical conductivity is also required.

Accordingly, the connector 16 can be made of a conductive ceramic material having high hardness, similar to the probe 20A.

For example, among the four components (members), the third plunger 161 and the fourth plunger 162 are made of conductive ceramic. Of course, all of the components, i.e., the third plunger 161, the fourth plunger 162, the barrel 163, and the coil spring 164, may be made of conductive ceramic. Alternatively, for example, the third plunger 161 and the fourth plunger 162 may be entirely made of conductive ceramic, or only a part thereof may be made of conductive ceramic.

(B-4) The structure of the vertical type probe illustrated in the above-described embodiments is not limited to that illustrated in FIG. 4. Although the vertical type probe illustrated in FIG. 4 is exemplified as being formed of four components, the number of components may not be limited to this example, and the vertical type probe may be formed of, for example, one component. Moreover, the shape of the vertical type probe is not limited to this example.

(B-5) In the above-described embodiments, the case where the probe is a vertical type probe has been exemplified, but the probe may be a cantilever type probe.

Also in the case of the cantilever type probe, the entire probe may be made of titanium carbonitride-based ceramic, or a part of the probe may be made of titanium carbonitride-based ceramic. Moreover, since the cantilever-type probe can be formed from a titanium carbonitride ceramic plate using electrical discharge machining or a similar process, it is easier to process than conventional metal materials.

(B-6) In the above-described embodiments, the electrical contactors according to the present disclosure are exemplified by the probe and the pogo pin. However, only the probe may be made of a conductive ceramic material. Alternatively, only the pogo pin may be made of a conductive ceramic material.

Alternatively, in the electrical connecting apparatus represented by a probe card, a conductive member may be made of conductive ceramic.

### REFERENCE SIGNS LIST

1: Probe device;
10: Housing;
11: First surface;
12: Second surface;
20: Probe;
20A: Probe;
21: First contact portion;
22: Second contact portion;
30: Elastic portion;
100: Device under test;
101: Electrode terminal;
31: First plunger;
32: Second plunger;
33: Coil spring;
53: Terminal;
54: Connection terminal;
62: Second plunger;
85: Connection terminal;
16: Connector;
161: Third plunger;
162: Fourth plunger;
163: Barrel;
164: Coil spring;
200: Substrate;
201: Electrode pad;
220: Contact region;
311: Coil receiving portion; and
321: Coil receiving portion.

1. An electrical contactor comprising:
a main body unit;
a first contact portion which is one tip portion of the main body unit and is in contact with a first contact object; and
a second contact portion which is the other tip portion of the main body unit and is in contact with a second contact object, wherein
the electrical contactor is made of a conductive ceramic material containing titanium.

2. The electrical contactor according to claim 1, wherein the entire electrical contactor is made of a material selected by the group consisting of a conductive ceramic material containing titanium carbonitride as a main component and a conductive ceramic material containing titanium carbonitride.

3. The electrical contactor according to claim 2, wherein the electrical contactor has a Vickers hardness of not less than approximately 800 HV and a volume resistivity of not more than approximately 60×10⁻⁶ Ω·cm.

4. The electrical contactor according to claim 2, wherein the electrical contactor has a Vickers hardness of not less than approximately 1000 HV and a volume resistivity of not more than approximately 100×10⁻⁶ Ω·cm.

5. An electrical connecting apparatus comprising a housing provided on a substrate on which wiring is formed, the electrical connecting apparatus configured to connect between an electrode portion of a device under test housed in the housing and the wiring, the electrical connecting apparatus comprising:
a plurality of contactors including a first contact portion in contact with the electrode portion of the device under test housed in the housing and a second contact portion in contact with the wiring formed on the substrate,
each contactor is the electrical contactor according to any one of claims 1 to 4.
